(19) United States
(12) Patent Application Publication
(10) Pub. No.: US 2006/0024864 A1
(43) Pub. Date: Feb. 2, 2006

(54) Substrate processing method

(75) Inventors: Toshio Nakanishi, Amagasaki-Shi (JP); Shigenori Ozaki, Amagasaki-Shi (JP); Masaru Sasaki, Amagasaki-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/211,495

(22) Filed: Aug. 26, 2005

Related U.S. Application Data
(63) Continuation-in-part of application No. PCT/JP04/02013, filed on Feb. 20, 2004.

(30) Foreign Application Priority Data
Feb. 28, 2003 (JP) 2003-054242

(51) Int. Cl. H01L 21/50

(52) U.S. Cl. 438/107

(57) ABSTRACT

A substrate processing method includes a first step of exposing a silicon substrate surface to mixed gas plasma of an inert gas and hydrogen, and a second step of conducting any of oxidation processing, nitridation processing and oxynitridation processing to said silicon substrate surface by plasma processing after said first step, wherein an organic substance remaining on said substrate surface is removed in said first step.

### CROSS-REFERENCE TO RELATED APPLICATIONS

The present invention is a continuation-in-part application of PCT/JP2004/002013 field on Feb. 20, 2004 based on Japanese priority application 2003-054242 filed on Feb. 28, 2003, the entire contents of each are incorporated by reference.

### BACKGROUND OF THE INVENTION

The present invention generally relates to substrate processing technology, and more particularly to a substrate processing method for forming an insulation film on a silicon substrate.

In semiconductor production technology, formation of insulation film on a silicon substrate is most fundamental and yet important technology. Especially, a very high quality insulation film is required for the gate insulation film, or the like, of MOS transistors. Meanwhile, the film thickness of the gate insulation film has been decreased to about 1 nm with device miniaturization with recent ultra-miniaturized high-speed semiconductor devices, and there is a need for the technology capable of forming such a thin insulation film with high quality.

Conventionally, high quality silicon oxide films used for the gate insulation film of a MOS transistor have been formed by thermal oxidation processing of a silicon substrate surface. A thermal oxide film of silicon thus formed has the feature of small number of dangling bonds, and there is caused little trapping of carriers even in the case the film is used for an insulation film covering the channel region and thus used in the environment in which the film is subjected to high electric field. Thereby, stable threshold characteristics are realized.

On the other hand, with the progress in the miniaturization technology, it is now becoming possible these days to produce ultra-miniaturized semiconductor devices having a gate length of 0.1 μm or less.

In order to improve the operational speed of semiconductor device with such ultra miniaturized semiconductor devices by way of reducing the gate length, there is a need of reducing the thickness of the gate insulation film in accordance with scaling law. In the case of a MOS transistor having the gate length of 0.1 μm, for example, there is a need of reducing the thickness of the gate insulation film to 2 nm or less. On the other hand, when the film thickness is decreased like this with a conventional thermal oxide film, there occurs an increase of gate leakage current in the form of tunneling current. From this reason, it has been thought that film thickness of 2 nm would be the limit of gate insulation film formed by a thermal oxide film. With a thermal oxide film having the film thickness of 2 nm, a gate leakage current of 1×10⁻²A/cm² has been realized.

Contrary to this, there is proposed a technology capable of forming a higher quality silicon oxide film by conducting oxidation processing to a silicon substrate, by using microwave plasma.

With the silicon oxide film thus formed by microwave plasma oxidation of silicon substrate, it has been confirmed that leakage current of 1×10⁻²A/cm² is possible with the application voltage of 1V, even in the case the film has a film thickness of 1.5 nm. Thus, it is expected that the silicon oxide film formed by microwave plasma enables breaking through of the foregoing limit of device miniaturization encountered in the conventional semiconductor devices that use a conventional thermal oxide film. Further, with the substrate processing that uses the microwave plasma, it becomes possible to form an oxynitride film or nitride having a large specific dielectric constant on a silicon substrate with the film quality exceeding the film quality of a thermal oxide film. In the case of using an oxynitride film for gate insulation film, a leakage current of 1×10⁻²A/cm² or less is realized at the application voltage of 1V for an oxynitride film having a film thickness equivalent to the film thickness of 1 nm of silicon oxide film.

Substrate processing by microwave plasma can be performed at a low temperature typically below 500° C., and because of this, it becomes possible to reduce the time needed for raising and lowering the substrate temperature. Thereby, it becomes possible to produce the semiconductor device with large throughput. Further, with such low temperature processing, there occurs no change of impurity concentration profile of diffusion regions even when the diffusion regions are already formed in the substrate, and it becomes possible to realize desired device characteristics with reliability.

Meanwhile, a gate insulation film is required to provide the feature of small leakage current and high reliability.

FIG. 1 shows the relationship between the accumulated defect rate F and integral electric charge amount (Qbd) leading to breakdown (TDDB: time dependent dielectric breakdown characteristic) for a silicon oxide film formed on a silicon substrate surface with the thickness of 10 nm by a microwave plasma oxidation processing conducted by the inventor of the present invention (shown in the drawing as “plasma oxide film”), in comparison with a thermal oxide film of the same thickness, wherein the vertical axis represents the accumulated defect rate F while the horizontal axis represents the integral electric charge amount Qbd that leads to insulation breakdown. It should be noted that the plasma oxide film has been formed by using a microwave plasma substrate processing apparatus to be explained later with FIG. 2, by oxidizing the silicon substrate surface already applied with removal process of native oxide film in the mixed gas plasma of argon and oxygen at the substrate temperature of 400° C.

Referring to FIG. 1, the line representing the accumulated defect rate F forms a steep gradient with regard to the integral electric charge amount Qbd in the case of the thermal oxide film, and thus, insulation breakdown occurs when the integral electric charge amount Qbd has reached a predetermined value. Such an insulation film has excellent reliability characterized predictable lifetime.

In the case of the plasma oxide film, on the other hand, the slope of the line representing the accumulated defect rate F is small, indicating that breakdown of the insulation film occurs with various values of the integrated electric charge amount. With such an insulation film, it is not possible to predict the device lifetime with certainty and no reliability is attained for the semiconductor device.

### SUMMARY OF THE INVENTION

Accordingly, it is a general object of the present invention to provide a novel and useful substrate processing method wherein the foregoing problems are eliminated.

Another and more specific object of the present invention is to provide a substrate processing method capable of forming an oxide film, a nitride film, or an oxynitride film on a silicon substrate surface by oxidation processing, nitridation processing or oxynitridation processing conducted in plasma with improved reliability and thus capable of assuring long device lifetime with the semiconductor device that uses such an insulation film.

Another object of the present invention is to provide a substrate processing method, comprising:

a first step of exposing a silicon substrate surface to mixed gas plasma of an inert gas and hydrogen; and

a second step of conducting any of oxidation processing, nitridation processing and oxynitridation processing to said silicon substrate surface by plasma processing after said first step.

According to the present invention, organic substance remaining on the substrate surface, is removed effectively by exposing the silicon substrate surface to the mixture gas plasma of the inert gas and the hydrogen gas before the substrate processing by plasma, and it becomes possible to form a very high-quality insulation film on a fresh silicon surface.

Other objects and further features of the present invention will become apparent from the detailed explanation of invention hereinafter when read in conjunction with the attached drawings.

### BRIEF DESCRIPTION OF THE DRAWING

FIG. 1 is a diagram showing the Qbd characteristic of a conventional thermal oxide film and a plasma oxide film;

FIGS. 2A and 2B are diagrams showing the construction of a plasma processing apparatus used with the present invention;

FIGS. 3A and 3B are diagrams showing the substrate processing according to a first embodiment of the present invention;

FIG. 4 is a diagram showing the Qbd characteristic of a plasma oxide film obtained with the first embodiment of the present invention;

FIG. 5 is a diagram showing the leakage current characteristic of the plasma oxide film obtained according to the first embodiment of the present invention;

FIG. 6A and 6B are diagrams showing the substrate processing according to a second embodiment of the present invention; and

FIGS. 7A and 7B are diagrams respectively showing the overall construction of the substrate processing system according to a third embodiment of the present invention including the substrate processing apparatus of FIGS. 2A and 2B.

### DESCRIPTION OF THE PREFERRED EMBODIMENT

### First Embodiment

The inventor of the present invention has acquired the knowledge, in an experimental investigation on the formation process of oxide films, nitride films and oxynitride films on a silicon substrate by microwave plasma processing, suggesting that organic substance remaining on the silicon substrate surface exerts a significant effect on the reliability of insulation film formed on the substrate.

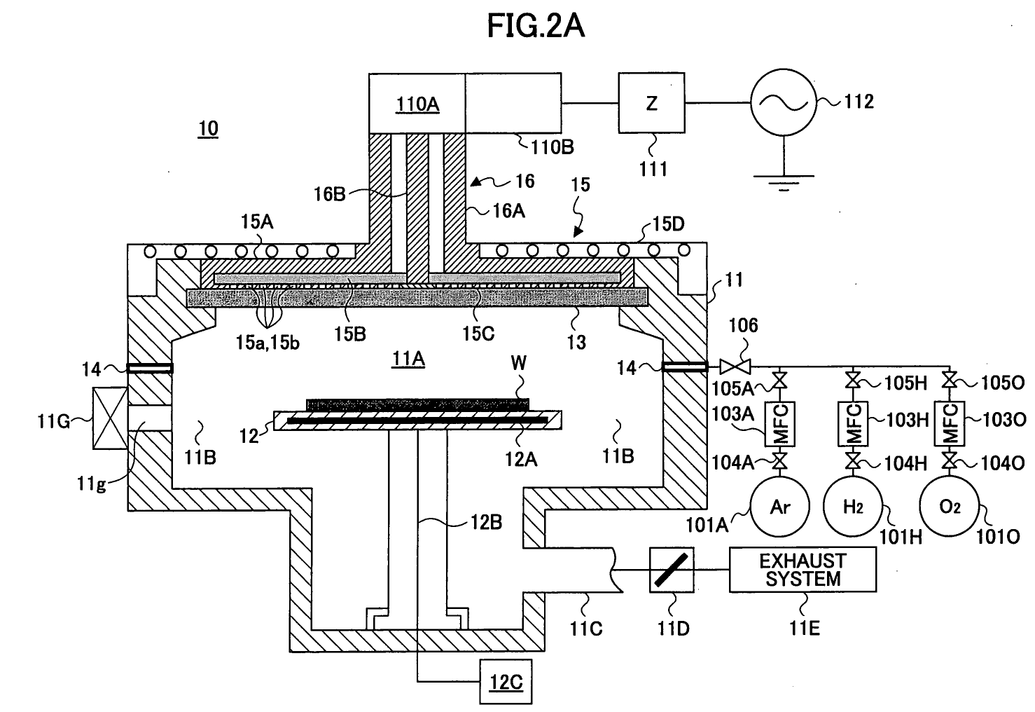

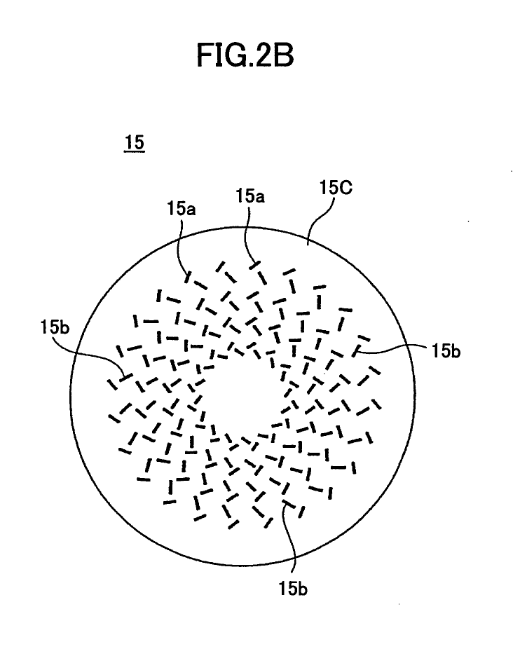

FIGS. 2A and 2B schematically show the construction a microwave plasma substrate processing apparatus 10 used by the inventor of the present invention.

Referring to FIG. 2A, the plasma substrate processing apparatus 10 includes a processing vessel 11 in which a processing space 11A is formed such that a stage 12 holding a substrate W to be processed thereon is formed in the processing space 11A, wherein the processing vessel 11 is evacuated by an evacuation system 11E at an evacuation port 11C via a space 11B surrounding the stage 12 and an adaptive pressure controller 11D.

The stage 12 is provided with a heater 12A, wherein the heater 12A is driven by a power source 12C via a line 12B.

Further, the processing vessel 11 is provided with a substrate in/out opening 11g and a gate valve 11G cooperating therewith for loading and unloading of the substrate W to be processed to and from the processing vessel 11.

On the processing vessel 11, there is formed an opening in correspondence to the substrate W to be processed on the stage 12, and the opening is closed by a top plate 13 of quartz or a low-loss dielectric such as alumina or AlN. Further, underneath the top plate 13, there are formed a gas ring 14 formed with a gas inlet path and a large number of nozzle openings communicating therewith such that the gas ring 14 faces the substrate W to be processed.

It should be noted that the cover plate 13 forms a microwave window, and a flat microwave antenna 15 of a radial line slot antenna is provided on the top part of the top plate 13. In place of the radical line slot antenna, it is also possible to use a horn antenna.

In the illustrated example, a radial line slot antenna is used for the flat microwave antenna 15, wherein it should be noted that the antenna 15 includes a flat conductor part 15A and a plane antenna plate 15C, wherein the plane antenna plate 15C is provided at the opening part of the flat conductor part 15A via a retardation plate 15B of quartz or alumina.

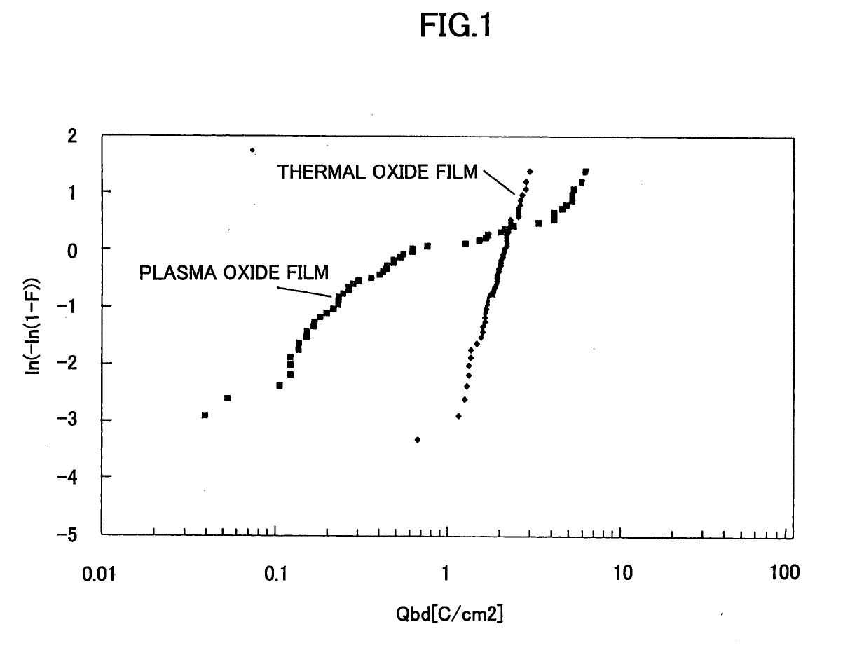

The plane antenna plate 15C is provided with a large number of slots 15a and 15b as will be explained with reference to FIG. 1B, wherein the antenna 15 is connected to a coaxial waveguide 16 having an outer conductor 16A connected to the conductor part 15A of the antenna 15 and a central conductor 16B connected to the plane antenna plate 15C through the retardation plate 15B. The coaxial waveguide 16 is connected to a rectangular waveguide 110B via a mode conversion part 110A, wherein the rectangular waveguide 110B is connected to a microwave source 112 via an impedance matcher 111. Thereby, the microwave source 112 supplies a microwave to the antenna 15 via the rectangular waveguide 110B and the coaxial waveguide 16.

Further, a cooling unit 15D is provided on the conductor part 15A.

FIG. 2B shows the construction of the radial line slot antenna.

Referring to FIG. 2B showing the radiation plate 15C in a plan view, it can be seen that the slots 15a and 15b are formed in a concentric relationship in such a manner that a slot 15a and an adjacent slot 15b form an angle of 90 degrees.

Thereby, the microwave supplied from the coaxial waveguide 16 spreads in the radial direction in the radial line slot antenna 15 with wavelength compression caused by the retardation plate 15B. Thereby, the microwave is emitted from the slits 15a and 15b generally in the direction perpendicular to the plane of the radiation plate 15C in the form of a circular polarized microwave.

Further, as shown in FIG. 2A, a rare gas source 101A such as an Ar gas source and a hydrogen gas source 101H are connected to the gas ring 14 via respective mass flow controllers 103A and 103H and via respective corresponding valves 104A, 104H, 105A, 105H and a common valve 106. As noted before, the gas ring 14 is provided with a large number of gas inlet ports around the stage 12 uniformly, and the rare gas and the hydrogen gas supplied to the gas ring 14 are introduced into the processing space 14A inside the processing vessel 11 uniformly. In addition, an oxygen gas source 1010 is connected to the gas ring 14 via a mass flow controller 1030 and valves 1040 and 1050 in the illustrated example for supplying oxygen to the processing vessel 11.

Further, although not illustrated, there may be provided other gas sources such as a nitrogen gas source, an ammonia gas source, a NO gas source, a N₂O gas source, a H₂O gas source, or the like.

In operation, the processing space inside the processing vessel 11 is set to a predetermined pressure by evacuating through the evacuation port 11C, and an oxidizing gas or a hydrogen gas is introduced from the gas ring 14 together with an inert gas such as Ar, Kr, Xe, Ne, Ne (rare gas) and the like.

Further, a microwave having the frequency of several GHz such as 2.45 GHz is introduced from the microwave source 112 via the antenna 15, and there is excited high-density microwave plasma in the processing vessel 11 at the surface of the substrate W to be processed with a plasma density of 10¹¹-10¹³/cm³. By exciting the plasma by the microwave introduced via the antenna, the plasma has low electron temperature of 0.7-2 eV or less, preferable 1.5 eV or less, with the substrate processing apparatus of FIG. 1A, and damaging of the substrate W or the inner wall of the processing vessel is avoided. Further, the radicals thus formed are caused to flow in the radial direction along the surface of the substrate W to be processed and are evacuated promptly. Thereby, recombination of the radicals is suppressed, and an extremely uniform and efficient substrate processing is realized at the low temperature of 550° C. or less.

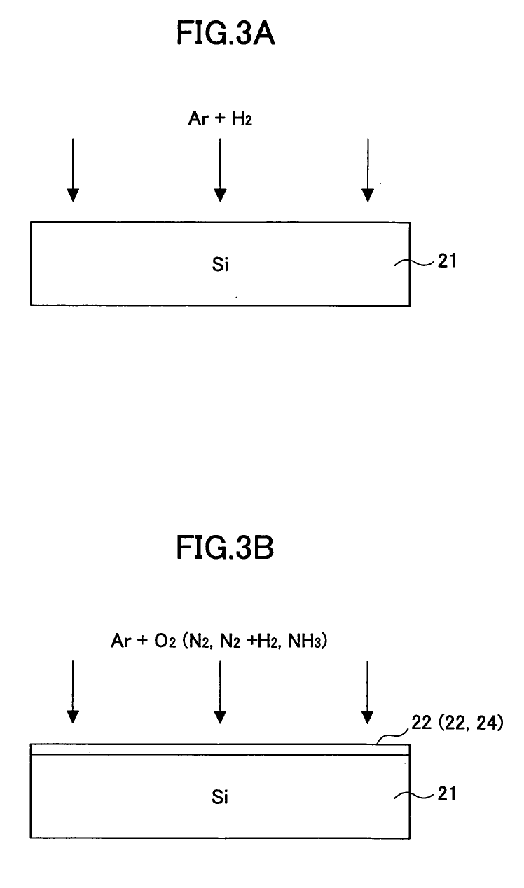

FIGS. 3A-3C are diagrams showing the substrate processing conducted by the inventor of the present invention in the investigation constituting the foundation of the present invention and corresponding to a first embodiment of the present invention, while using substrate processing apparatus 10 of FIG. 1.

Referring to FIG. 3A, a silicon substrate 21, from which the native oxide film is removed by a diluted HF solution (1% HF concentration, for example), is introduced to the processing vessel 11 of the substrate processing apparatus 10 as the substrate W to be processed, and a mixed gas of argon and hydrogen is introduced from the shower plate 14. Further, plasma is formed by exciting the mixed gas by a microwave. Thereby, it is possible to form the plasma stably and with uniformity as a result of use of the Ar gas for the plasma gas.

In an example, the process pressure inside the processing vessel 11 is set to 7 Pa, and an argon gas and a hydrogen gas are supplied with respective flow rates 1000 SCCM and 40 SCCM. Further, a microwave of 2.4 GHz in frequency is supplied to the microwave antenna 15 with the power of 1500 W at the substrate temperature of 400° C., and high density plasma is formed uniformly and stably in the vicinity of the surface of the substrate W to be processed.

With the step of FIG. 3A, an organic substance remaining on the substrate surface is removed effectively in the form of hydrocarbons as a result of exposing the surface of the silicon substrate 21 to the plasma thus formed, even at a low substrate temperature of 400° C., and a fresh silicon surface is exposed at the substrate surface.

Next, in the step of FIG. 3B, a silicon oxide film 22 is formed on the silicon substrate 21 thus applied with the processing of FIG. 3A with the thickness of 1-10 nm, by setting the processing pressure inside the processing vessel 11 to typically 7 Pa and supplying an argon gas and an oxygen gas with respective flow rates of 1000 SCCM and 40 SCCM, while setting the substrate temperature to 400° C. and by supplying the microwave of 2.4 GH frequency to the microwave antenna 15 with the power of 1500 W.

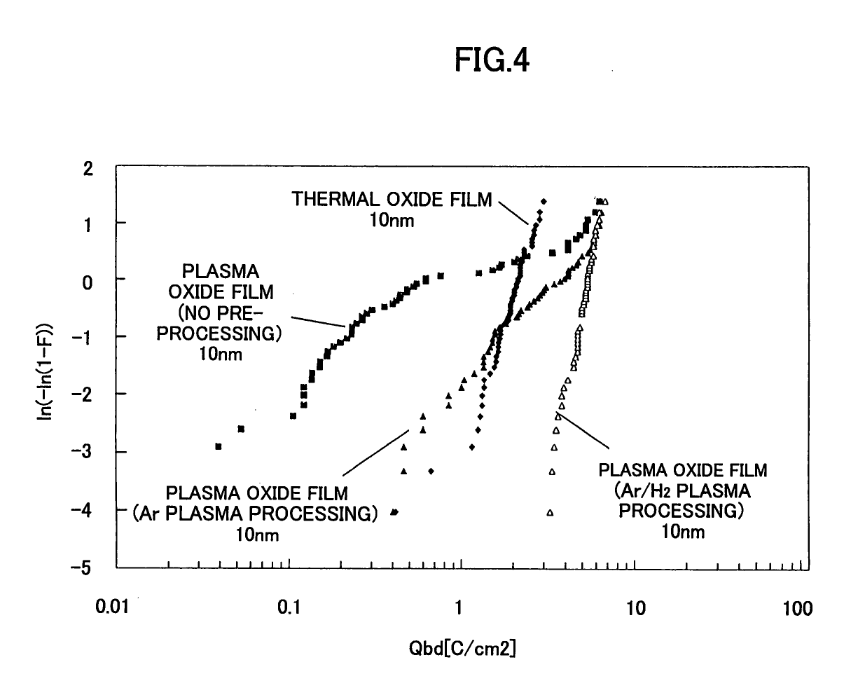

FIG. 4 shows the relationship between the accumulated defect rate F and the breakdown electric charge amount Qbd for the silicon oxide film thus obtained in comparison with the result of FIG. 1. Further, FIG. 4 also shows the result for the case in which the silicon substrate 21 is exposed to the argon plasma in the step of FIG. 3A. In FIG. 4, the silicon oxide film is formed to the thickness of 10 nm.

Referring to FIG. 4, it should be noted that the process in which the pre-processing of FIG. 3A is omitted, and thus, the silicon oxide film 22 is formed on the silicon substrate 21 directly with the thickness of 10 nm, corresponds to the plasma oxide film explained previously with reference to FIG. 1, wherein it will be noted that there appears a large variation of breakdown electric charge amount Qbd as explained already with reference to FIG. 1.

Contrary to this, in the case the argon plasma processing is conducted in the pre-processing step of FIG. 3A, it can be seen that variation of the breakdown electric charge amount Qbd is decreased. Particularly, in the case the pre pre-processing is conducted in the mixed gas plasma of argon and hydrogen as shown in FIG. 3A, the variation of the breakdown electric charge mount Qbd is decreased further, and a result comparable to the case of a thermal oxide film is attained. Thus, by carrying out the pre-processing process of FIG. 3A in the mixture gas plasma of argon and hydrogen, it can be seen that a plasma oxide film having the reliability comparable to that of a thermal oxide film is obtained.

Moreover, as can be seen from FIG. 4, the absolute value of the breakdown electric charge amount Qbd of the plasma oxide film of the present embodiment is increased further as compared with the case of thermal oxide film, indicating that the lifetime of the obtained plasma oxide film is increased.

The fact shown in FIGS. 1 and 4 that the variation of the breakdown electric charge amount Qbd is small in the thermal oxide film formed in the oxidizing ambient at high temperatures and that the breakdown electric charge amount Qbd is large in the plasma oxide film formed at the low temperature of about 400° C., suggests that this phenomenon is related to organic substances remaining on the surface of the silicon substrate 21. In the present embodiment, it is thought that, as a result of the processing of the surface of the silicon substrate 21 in the mixed gas plasma of argon and hydrogen in the step of FIG. 3A, the organic substance remaining on the silicon substrate surface is removed therefrom in the form of hydrocarbons, and a fresh silicon surface is exposed at the silicon substrate at the commencement of the step of FIG. 3B.

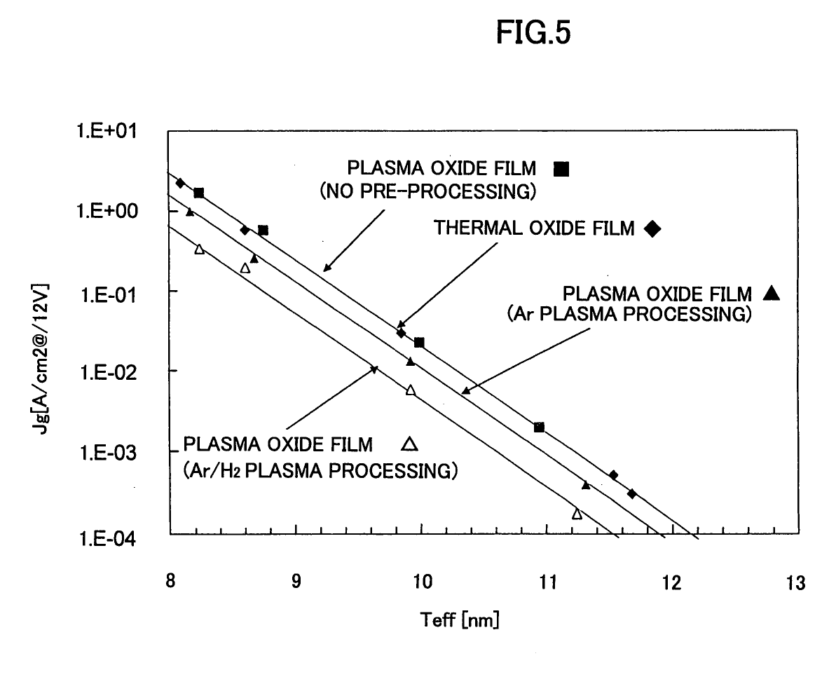

FIG. 5 shows the leakage current characteristics of the silicon oxide film 22 thus formed with the film thickness of 10 nm, wherein the measurement of FIG. 5 is conducted under the condition of applying a voltage of 12V, and thus, the values are different from the case explained previously in which the measurement was made by applying a voltage of 1V.

Referring to FIG. 5, with the plasma oxide film shown in FIG. 1 in which the pre-processing step of FIG. 3A is omitted, a leakage current density comparable with that of a conventional thermal oxide film is obtained, while in the case in which the plasma pre-processing by argon gas is conducted in the step of FIG. 3A, there is caused a decrease of leakage current, particularly in the case the pre-processing process of FIG. 3A is conducted in the mixed gas plasma of argon and hydrogen.

Further, while formation of silicon oxide film has been made in the present embodiment on the surface of the silicon substrate 21 in the step of FIG. 3B by the mixed gas plasma of argon and hydrogen, it is also possible to form a silicon nitride film 23 by using argon and nitrogen, or argon and ammonia, or argon and a mixed gas of nitrogen and hydrogen. Further, it is also possible to form a silicon oxynitride film 24 by using argon and nitrogen and oxygen, or argon and ammonia and oxygen, or argon and a mixed gas of nitrogen and hydrogen and oxygen.

Further, it is also possible to use an inert gas of other rare gas such as helium, krypton and xenon, in place of argon with the present embodiment.

Further, it is possible with the present embodiment to use other oxidizing gas or nitriding gas such as NO, N₂O, H₂O, or the like in the present invention, in place of the oxygen gas, nitrogen gas and ammonia gas.

### Second Embodiment

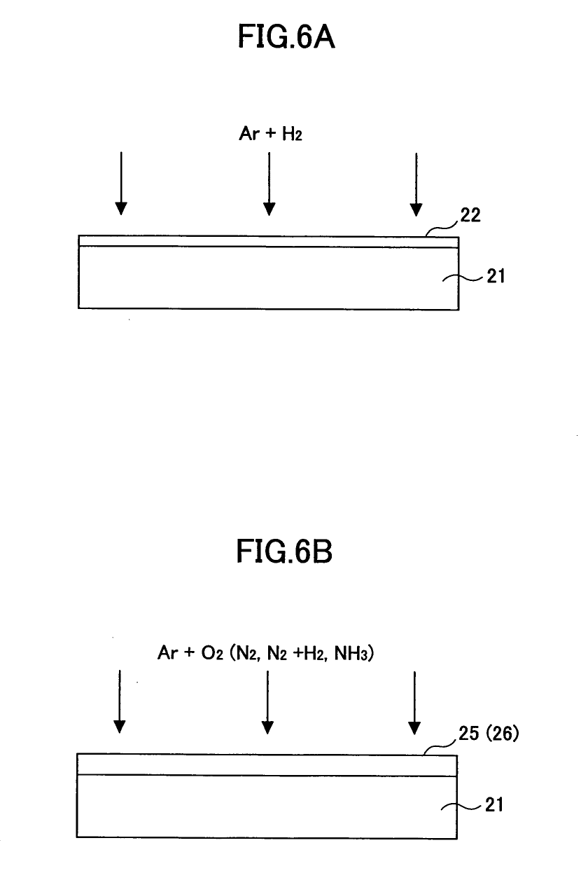

FIGS. 6A and 6B show the substrate processing method according to a second embodiment of the present invention.

Referring to FIG. 6A, there is formed a silicon oxide film 22 on a silicon substrate 21 by the process of FIGS. 3A and 3B explained before or by other process, wherein the surface of the silicon oxide film 22 is processed by the mixture gas plasma of argon and hydrogen under the condition similar to the process of FIG. 3A, and the organic substance remaining on the surface of the silicon oxide film 22 is removed.

Next, in the step of FIG. 6B, there is caused a growth of the oxide film on the silicon oxide film 22 thus processed by applying the mixed gas plasma of argon and oxygen under the similar condition as FIG. 3B, and with this, there is formed an oxide film 25.

It should be noted that the oxide film 25 thus formed has excellent reliability and leakage current density similarly to the plasma oxide film that explained with the previous embodiment.

Further, in the process of FIG. 6B, it is possible to form a silicon oxynitride film 26 by nitriding the silicon oxide film 22 by using argon and nitrogen, or argon and ammonia, or the mixed gas plasma of argon and nitrogen and hydrogen.

Further, while explanation has been made for the present embodiment for the case of using the microwave plasma substrate processing apparatus of FIGS. 2A and 2B that uses the radial line slot antenna 15, it is also possible to omit the shower plate 14 in the construction of FIG. 2A and introduce the gases from the gas inlet part 14A directly into the processing vessel 11. Further, the present invention is not limited to such a particular substrate processing apparatus, but is effective also in a parallel plate plasma processing apparatus, an ICP plasma processing apparatuses, an ECR plasma processing apparatus, and the like.

### Third Embodiment

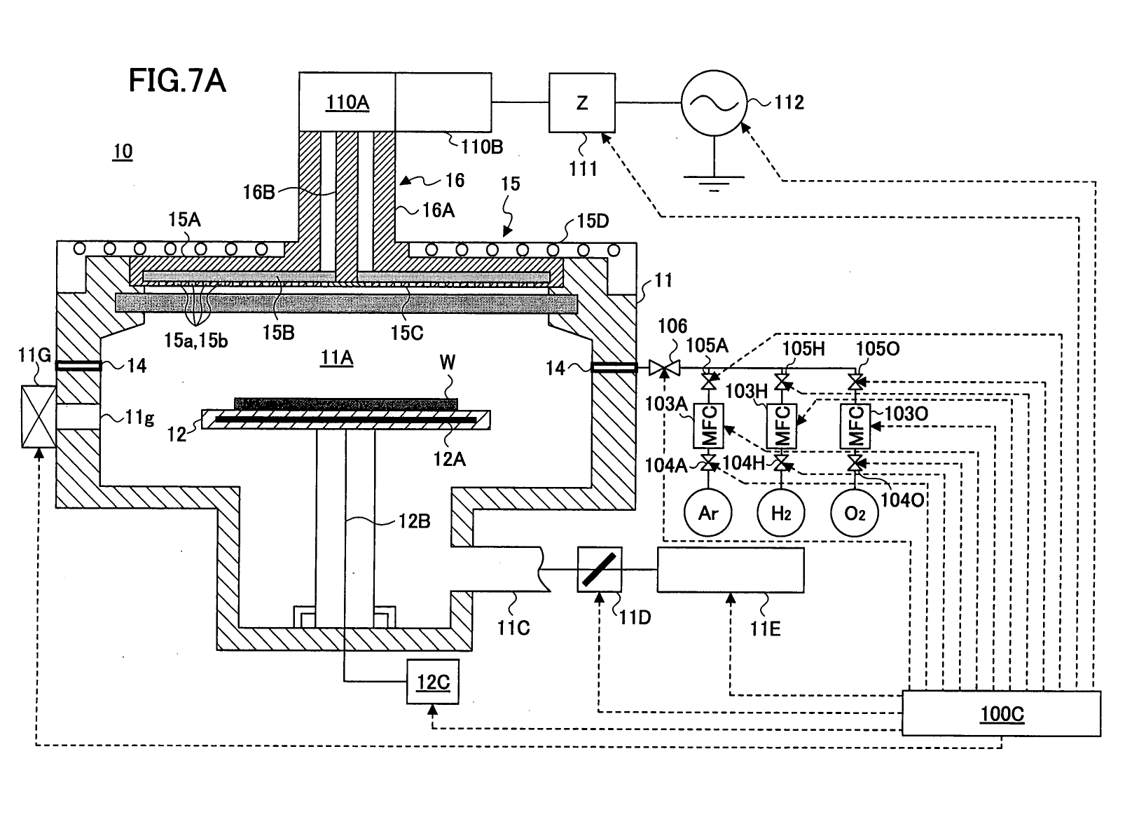

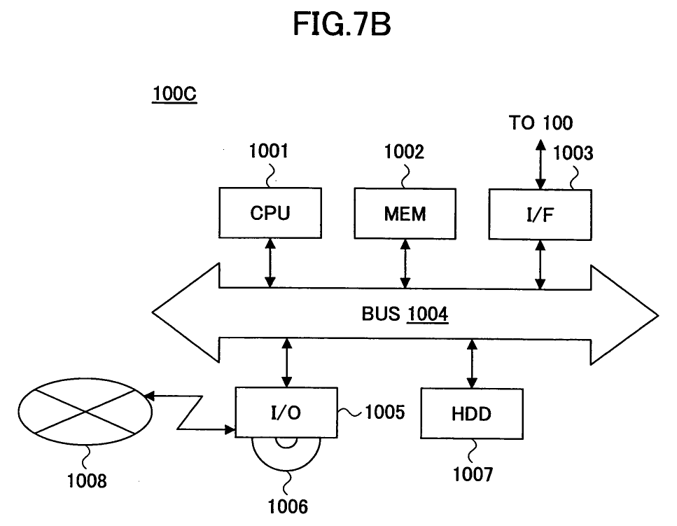

FIGS. 7A shows the construction of an overall substrate processing system 100 that includes the substrate processing apparatus 10 of FIGS. 2A and 2B and used for the processing of the present invention of FIGS. 3A and 3B or FIGS. 6A and 6B, while FIG. 7B shows a computer used for controlling the substrate processing apparatus 10 of FIGS. 2A and 2B in the system of FIG. 8A.

Referring to FIG. 7A, the system 100 includes the Ar gas source 101A, the hydrogen gas source 101H and the oxygen gas source 1010, wherein the Ar gas source 101A supplies an Ar gas to the gas ring 14 of the substrate processing apparatus 10 via the mass flow controller 103A and via the valves 104A and 105A and further via the valve 106, while the hydrogen gas source 101H supplies a hydrogen gas to the gas ring 14 via the mass flow controller 103H and via the valves. 104H and 105H and further via the valve 106 coupled to the gas ring 14 commonly to the gas supply path of the Ar gas and the gas supply path of the hydrogen gas. Further, the oxygen gas source 1010 supplies an oxygen gas to the gas ring of the substrate processing apparatus 10 via the mass flow controller 1030 and the valves 1040, 1050 and the valve 106.

Further, the system 100 includes the microwave power source 112 that supplies the microwave power to the radial line slot antenna 15 via an impedance matcher 111.

Further, the heating mechanism 12A is provided in the stage 12 for temperature control of the substrate W to be processed.

Further, the system 100 includes the evacuation system 11E coupled to the evacuation port 11C via the adaptive pressure controller 11D.

Further, the system 100 includes the gate valve 11G cooperating with the substrate in/out opening 11g provided on the processing vessel 11 for loading and unloading the substrate W to be processed to and from the processing vessel 11.

Further, it should be noted that there is provided a system controller 100C that controls the mass flow controllers 103A, 103B, and 1030, valves 104A, 104H, 1040, 105A, 105H, 1050 and 106, the heating mechanism 12H, an evacuation pump not illustrated, and further the gate valve 11G according to the program held therein, and the substrate processing apparatus 10 performs the foregoing hydrogen radical processing or oxidation processing under control of the controller 100C.

FIG. 7B shows the construction of the controller 100C.

Referring to FIG. 7B, the controller 100C is a general purpose computer and includes a CPU 1001, a memory 1002 holding a program and data, an interface unit 1003 connected to the system 100, and an I/O interface 1005 connected with each other by a system bus 1004, wherein the computer 100C is provided with the control program of the substrate processing system 100 from a recording medium 1006 such as an optical disk or a floppy disk or from a network 1007 and controls the substrate processing system 100 of FIG. 7A including the substrate processing apparatus 10 via the interface unit 1003.

Thus, the present invention also includes such a computer configured by the program code means recorded on a processor-readable medium and also the processor readable medium that carries such a program code.

Further, while the present invention has been explained heretofore with regard to preferred embodiments, the present invention is not limited to such a particular embodiment but various variations and modifications may be made within the subject matter recited in claims.

What is claimed is:

1. A method of processing a substrate in a processing vessel by plasma, comprising:
a first step of: supplying an inert gas and a hydrogen gas into said substrate processing vessel to form a first mixed gas therein; forming first plasma by exciting said first mixed gas in said processing vessel via an antenna; and exposing a surface of said substrate to said first plasma; and
a second step of: supplying, after said first step, any of an inert gas and an oxygen gas, an inert gas and a gas containing nitrogen, an inert gas and an oxygen gas and a gas containing nitrogen, an inert gas and a gas containing nitrogen and a hydrogen gas, an inert gas and a gas containing nitrogen and a hydrogen gas and an oxygen gas, into said processing vessel to form a second mixed gas therein; forming second plasma in said processing vessel by exciting said second mixed gas via said antenna; and exposing said surface of said substrate to said second plasma to form any of an oxide film, a nitride film and an oxynitride film on said substrate.

2. The method as claimed in claim 1, wherein said first step and said second step are conducted in said processing vessel consecutively and in continuation.

3. The method as claimed in claim 1, wherein said first plasma in said first step and said second plasma in said second step are formed by supplying a microwave into said processing vessel via said antenna.

4. The method as claimed in claim 1, wherein said antenna includes plurality of slots on an emission surface.

5. The method as claimed in claim 1, wherein a silicon surface is exposed at a surface of said substrate in said first step.

6. A method of processing a substrate in a processing vessel by plasma, comprising the steps of:
forming an insulation film on said substrate;
disposing said substrate in said processing vessel,
said method further comprising:
a first step of: supplying an inert gas and a hydrogen gas into said substrate processing vessel to form a first mixed gas therein; forming first plasma by exciting said first mixed gas in said processing vessel via an antenna; and exposing a surface of said substrate to said first plasma; and
a second step of: supplying, after said first step, any of an inert gas and an oxygen gas, an inert gas and a gas containing nitrogen, an inert gas and an oxygen gas and a gas containing nitrogen, an inert gas and a gas containing nitrogen and a hydrogen gas, an inert gas and a gas containing nitrogen and a hydrogen gas and an oxygen gas, into said processing vessel to form a second mixed gas therein; forming second plasma in said processing vessel by exciting said second mixed gas via said antenna; and exposing said surface of said substrate to said second plasma to form any of an oxide film, a nitride film and an oxynitride film on said substrate.

7. The method as claimed in claim 6, wherein said first step and said second step are conducted in said processing vessel consecutively and in continuation.

8. The method as claimed in claim 6, wherein said first plasma in said first step and said second plasma in said second step are formed by supplying a microwave into said processing vessel via said antenna.

9. The method as claimed in claim 6, wherein said antenna includes plurality of slots on an emission surface.

10. The method as claimed in claim 6, wherein a silicon surface is exposed at a surface of said substrate in said first step.

11. A computer-readable medium storing program code means for configuring a general purpose computer to cause a substrate processing apparatus to carry out a method of processing a substrate in a processing vessel by plasma, comprising:
a first step of: supplying an inert gas and a hydrogen gas into said substrate processing vessel to form a first mixed gas therein; forming first plasma by exciting said first mixed gas in said processing vessel via an antenna; and exposing a surface of said substrate to said first plasma; and
a second step of: supplying, after said first step, any of an inert gas and an oxygen gas, an inert gas and a gas containing nitrogen, an inert gas and an oxygen gas and a gas containing nitrogen, an inert gas and a gas containing nitrogen and a hydrogen gas, an inert gas and a gas containing nitrogen and a hydrogen gas and an oxygen gas, into said processing vessel to form a second mixed gas therein; forming second plasma in said processing vessel by exciting said second mixed gas via said antenna; and exposing said surface of said substrate to said second plasma to form any of an oxide film, a nitride film and an oxynitride film on said substrate.

12. The computer-readable medium as claimed in claim 11, wherein said first step and said second step are conducted in said processing vessel consecutively and in continuation.

13. The computer-readable medium as claimed in claim 11, wherein said first plasma in said first step and said second plasma in said second step are formed by supplying a microwave into said processing vessel via said antenna, said antenna includes plurality of slots on an emission surface.

14. The computer-readable medium as claimed in claim 11, wherein a silicon surface is exposed at a surface of said substrate in said first step.

15. A computer-readable medium storing program code means for configuring a general purpose computer to cause a substrate processing apparatus to carry out a method of processing a substrate in a processing vessel by plasma, comprising the steps of:
forming an insulation film on said substrate;
disposing said substrate in said processing vessel,
said method further comprising:
a first step of: supplying an inert gas and a hydrogen gas into said substrate processing vessel to form a first mixed gas therein; forming first plasma by exciting said first mixed gas in said processing vessel via an antenna; and exposing a surface of said substrate to said first plasma; and
a second step of: supplying, after said first step, any of an inert gas and an oxygen gas, an inert gas and a gas containing nitrogen, an inert gas and an oxygen gas and a gas containing nitrogen, an inert gas and a gas containing nitrogen and a hydrogen gas, an inert gas and a gas containing nitrogen and a hydrogen gas and an oxygen gas, into said processing vessel to form a second mixed gas therein; forming second plasma in said processing vessel by exciting said second mixed gas via said antenna; and exposing said surface of said substrate to said second plasma to form any of an oxide film, a nitride film and an oxynitride film on said substrate.

16. The computer-readable medium as claimed in claim 15, wherein said first step and said second step are conducted in said processing vessel consecutively and in continuation.

17. The computer-readable medium as claimed in claim 15, wherein said first plasma in said first step and said second plasma in said second step are formed by supplying a microwave into said processing vessel via said antenna, said antenna includes plurality of slots on an emission surface.

18. The computer-readable medium as claimed in claim 15, wherein a silicon surface is exposed at a surface of said substrate in said first step.
